(19) United States
(12) Patent Application Publication
(10) Pub. No.: US 2014/0166077 A1
(43) Pub. Date: Jun. 19, 2014

(54) SOLAR CONCENTRATION SYSTEM

(71) Applicant: Skyven Technologies, LLC, Dallas, TX (US)

(72) Inventor: Arun K. Gupta, Dallas, TX (US)

(73) Assignee: Skyven Technologies, LLC, Dallas, TX (US)

(21) Appl. No.: 14/109,495

(22) Filed: Dec. 17, 2013

Related U.S. Application Data
(60) Provisional application No. 61/738,052, filed on Dec. 17, 2012.

(51) Int. Cl. F24J 2/38; H01L 31/18; H01L 31/052

(52) U.S. Cl. CPC F24J 2/38; H01L 31/0521; H01L 31/0525; H01L 31/18
USPC 136/246; 126/600; 126/601; 29/890.033

(57) ABSTRACT

Embodiments of a system and method for collecting electromagnetic radiation are disclosed. One embodiment of a solar concentration system comprises at least one collector panel, the panel comprising a frame and a plurality of moveable reflector elements mounted therewithin, the plurality of movable reflector elements configured to rotate in unison about a set of parallel first axes and in unison about a second axis relative to an electromagnetic radiation source. The system further comprises at least one receiver comprising a support member and a plurality of energy conversion cells positioned along the support member, each energy conversion cell having an electromagnetic radiation concentrator protruding therefrom, the concentrator comprising an optical element and an entry aperture at a distal end thereof. The plurality of movable reflector elements are configured to reflect electromagnetic radiation from the source onto the at least one receiver for transforming electromagnetic radiation into electrical or thermal energy.

### CLAIM OF PRIORITY

This application claims priority to provisional Application Ser. No. 61/738,052 filed Dec. 17, 2012, the entire contents of which are incorporated herein by reference.

### FIELD OF THE DISCLOSURE

The present disclosure relates generally to solar energy, and more particularly, to a system for collecting and concentrating solar irradiation and converting the collected irradiation into usable electrical and/or thermal energy.

### BACKGROUND

Solar collectors that concentrate sunlight with a high concentration factor (>100×) generally take the form of parabolic troughs, parabolic dishes, power towers, or Fresnel lenses. As all of these collectors may physically move and track the sun, they may be constructed of strong and sturdy materials that are able to withstand wind loads. They may also employ powerful precision drive mechanisms to implement the solar tracking. Non-concentrating or low-concentration collectors can remain stationary, allowing lower-cost and lower strength structural design. However, the benefits of high concentration systems over non-concentrating or low-concentration systems are that of very low area high efficiency photovoltaic cells or high temperature thermal collection or both (e.g., cogeneration). In order to achieve the lowest overall cost, there is a need for a collector system that achieves the benefits of both categories.

### SUMMARY

The present disclosure provides a system and method for collecting solar irradiation and converting it to electrical energy, heat energy, or both.

In one embodiment a panel is disclosed. The panel comprises a frame; and a plurality of moveable reflector elements mounted within the frame, the plurality of movable reflector elements configured to rotate in unison about a set of parallel first axes and in unison about a second axis relative to an electromagnetic radiation source. The plurality of movable reflector elements are configured to reflect electromagnetic radiation from the electromagnetic radiation source onto an energy transformation medium for transforming the electromagnetic radiation into electrical or thermal energy.

In another embodiment, a solar concentration system is disclosed comprising at least one solar collector panel and at least one receiver. The panel may comprise a frame and a plurality of moveable reflector elements mounted within the frame, the plurality of movable reflector elements configured to rotate in unison about a set of parallel first axes and in unison about a second axis relative to the sun. The receiver may comprise a support member and a plurality of energy conversion cells positioned along the support member at regular intervals, each energy conversion cell having an electromagnetic radiation concentrator protruding therefrom, the electromagnetic radiation concentrator comprising an optical element and an entry aperture at a distal end thereof. The plurality of movable reflector elements are configured to reflect electromagnetic radiation from the sun onto the at least one receiver for transforming the electromagnetic radiation into electrical or thermal energy. In some embodiments, the support member includes a heat sink thermally coupled to the plurality of energy conversion cells.

In yet another embodiment, there is disclosed a method of manufacturing a panel. The method comprises forming a frame; forming a plurality of moveable reflector elements to be mounted within the frame, the plurality of movable reflector elements configured to rotate in unison about a set of parallel first axes and in unison about a second axis relative to an electromagnetic radiation source; and configuring the plurality of movable reflector elements to reflect electromagnetic radiation from the electromagnetic radiation source onto an electromagnetic radiation transformation medium for transforming the electromagnetic radiation into electrical or thermal energy.

### BRIEF DESCRIPTION OF THE DRAWINGS

FIG. 1 is a perspective view of one embodiment of a solar concentration system according to the present disclosure;

FIG. 2 is a perspective view of an embodiment of a solar concentration system with incident solar rays of solar radiation illustrated;

FIG. 3 is a side view of an embodiment of a solar concentration system with incident solar rays of solar radiation illustrated;

FIG. 4 is a top view of an embodiment of a solar concentration system with incident solar rays of solar radiation illustrated;

FIG. 5 is a perspective view of a single panel which may be used in the system shown in FIGS. 1 and 2;

FIG. 6 is a side sectional view of a housing for the single collector panel shown in FIG. 5;

FIG. 7 is a perspective view of a single reflector element which may be used in the system shown in FIGS. 1 and 2 and panel as shown in FIG. 5;

FIG. 8 is a perspective view of one end of a row of reflector elements;

FIG. 9 is a perspective view of one end of a row of reflector elements connected to a housing frame;

FIG. 10 is a perspective view of links of a mechanical drive system which may be used with the solar collection system according to the present disclosure;

FIG. 11 is a perspective view of drive shafts of a mechanical drive system which may be used with the solar collection system according to the present disclosure;

FIG. 12 is a perspective view of a photovoltaic cell assembly which may be used in the solar collection system according to the present disclosure;

FIG. 13 is a perspective view of a liquid coolant pipe assembly which may be used in the solar collection system according to the present disclosure;

FIG. 14 is a perspective view of a full receiver which may be used in the solar collection system according to the present disclosure;

FIG. 15 is an enlarged view of the receiver shown in FIG. 14;

FIG. 16 is a perspective view of modular rows of collector panels which may be installed according to the present disclosure;

FIG. 17 is an enlarged view of the rows shown in FIG. 16 illustrating another aspect of the present disclosure; and

FIG. 18 is a perspective view of another embodiment of a solar collection system according to the present disclosure.

### DETAILED DESCRIPTION OF THE DRAWINGS

Described herein is a system and method for collecting solar irradiation and converting it to electrical energy, heat energy, or both. The system may comprise, in one embodiment, a plurality of flat panel collectors that reflect light from an electromagnetic radiation source, such as, for example, the sun, and concentrate the electromagnetic radiation source onto a plurality of receivers. In one embodiment, the flat panel collectors concentrate the light in at least one axis, in the vertical direction, but not in the horizontal direction. In the horizontal axis, light is generally not concentrated, but it is reflected so it hits the entry aperture of receivers normal to the entry aperture. Each panel further comprises a housing that contains hundreds of small internal moving reflector elements that move in unison as they track the electromagnetic radiation source while the housing itself remains stationary. A mechanical drive system allows one or more (e.g., all in one embodiment) reflector elements to track the electromagnetic radiation source in two axes while being driven by a reduced number of electric motors. In one embodiment, the reflector elements are manufactured from injection molded plastic that is laminated with a metalized film, resulting in light weight and low cost. In this embodiment, the reflector elements have a slight curvature along one axis in the shape of a two-dimensional parabola with a focus coinciding with the position of the receiver. This allows each reflector elements to provide at least 2× concentration. The reflector elements are protected by the panel housing, which comprises a frame made of a rigid material such as extruded aluminum. An optically transparent sheet such as acrylic or glass is attached to the front of the frame and backing is attached to the back of the frame. The window seals out moisture, wind, and particulates and provides protection from ultraviolet radiation, resulting in good reliability, low maintenance, and easy cleaning. Incident light, including solar radiation, shines through the transparent sheet, where it is reflected by the reflector elements back through the transparent sheet towards the receiver.

Each receiver, in one embodiment, comprises an array of secondary concentrator optic elements that concentrate the solar radiation onto an energy transformation medium that transforms the solar radiation into electricity, heat, or both. In one embodiment, total optical concentration factor is approximately 800×. In this embodiment, the energy transformation medium comprises liquid-cooled triple junction photovoltaic cells, which produce electricity and may also be used to heat water. The triple junction photovoltaic cells may be attached to a liquid cooling pipe that carries water. The photovoltaic cells may get very hot from incident solar radiation, and the heat may be transferred to a heat sink, such as a pipe having the water flowing therethrough. The heated water can then be piped away and used remotely, in applications such as building heating, and various other uses for heated water. However, other energy transformation medium, such as air cooled photovoltaic cells, thermal absorber, thermionic emission device, or photo-enhanced thermionic emission device, are also envisioned.

The secondary concentrator, in one embodiment, is designed with non-imaging optics to be very tolerant of optical error in the system, especially for such a high concentration ratio. In one embodiment it comprises a two-axis compound parabolic concentrator that allows for about +/−3° and about +/−0.6° optical errors in the two axes respectively. In another embodiment, the secondary concentrator may only concentrate the electromagnetic radiation source, such as the sun, in only one axis that is parallel with a horizontal plane of the heat pipe horizontal. In other embodiments, the secondary concentrator may concentrate the light in both an axis parallel to the horizontal plane and a second axis parallel with the vertical plane.

The panels may be oriented at about 45° from horizontal and arranged in rows facing south, in one embodiment. Receivers for a given row may be mounted on the back of the preceding row. An integrated modular interconnecting racking system may be configured to maintain precise spacing between rows and is self-ballasting, allowing rapid installation without the need to drill holes in the roof or add extra ballast weight. This provides an aerodynamic low profile system that is well-suited for flat commercial rooftops. The height of the system in one embodiment is approximately 3 feet.

Additional features of the disclosure are as follows: Hot water piping across each row can be integrated into the collector/racking, minimizing plumbing requirements at installation. The electrical design may integrate a micro-inverter with the solar tracker and motor controller for each panel, resulting in further cost savings. The panel-level maximum power point tracking (MPPT) increases overall efficiency by avoiding mismatch due to soiling, shading, and temperature gradients. Alternating current or direct current cabling across each row may also be integrated into the collector/racking, further simplifying installation and reducing cost.

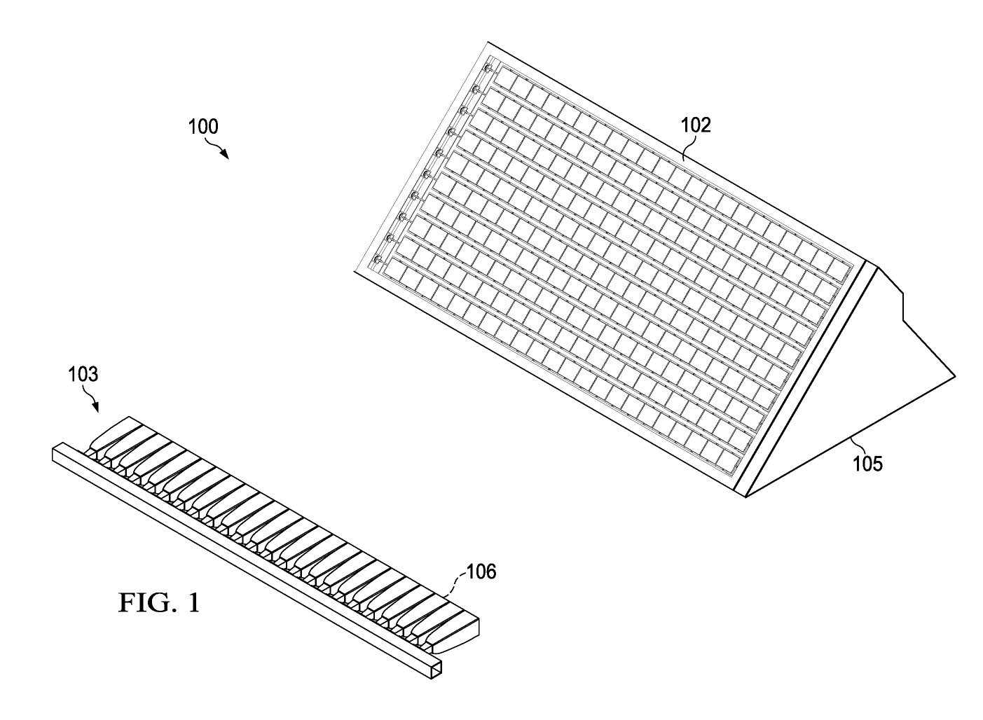

Referring now to the drawings in more detail, FIG. 1 is a perspective view of a solar collection system 100. The collection system 100 comprises a solar collector panel 102 having a length L, a solar receiver 103, and a panel rack 105. The receiver 103 may be located in front of the panel 102 and oriented substantially parallel to the panel 102. The receiver 103 comprises an aperture 106 having a long narrow rectangle shape that has a substantially similar length as length L of the collector panel 102 but substantially more narrow in width relative to the collector panel 102 such that collector panel 102 concentrates incoming solar radiation A in a vertical direction but not in a horizontal direction.

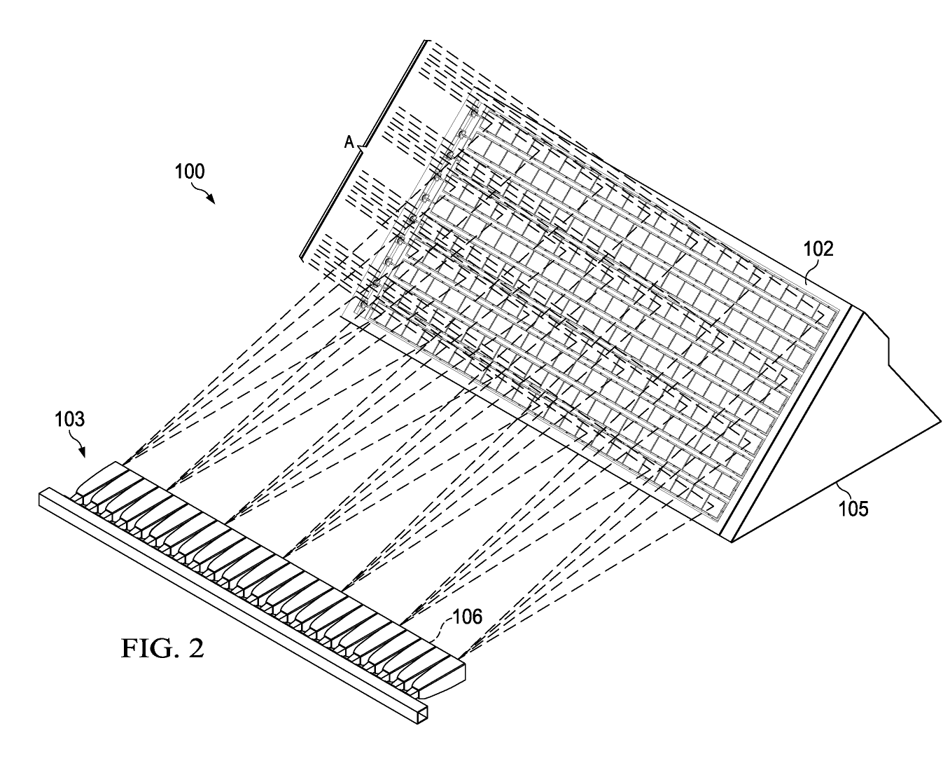

FIG. 2 is a perspective view of the solar collection system 100 with incident solar rays of solar radiation A projected thereon. Incoming rays of solar radiation A are reflected by collector panel 102 into receiver 103, where they are converted into electricity, heat, or both. Collector panel 102 may comprise internal reflector elements that track the sun such that no matter where the sun is in the sky, the incident rays of solar radiation A are always reflected into the receiver 103. Collector panel 102 may be mounted on top of rack 105 such that the collector panel 102 is positioned at an angle. In one embodiment, as shown in FIG. 2, the panel may be positioned at about a 45 degree angle to the horizontal. Other embodiments may position the panels 102 at angles between about 20 degrees and about 70 degrees.

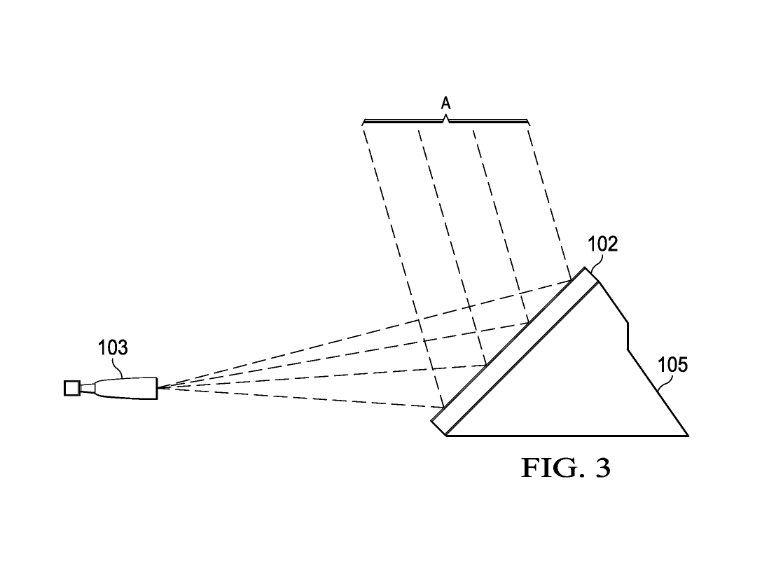

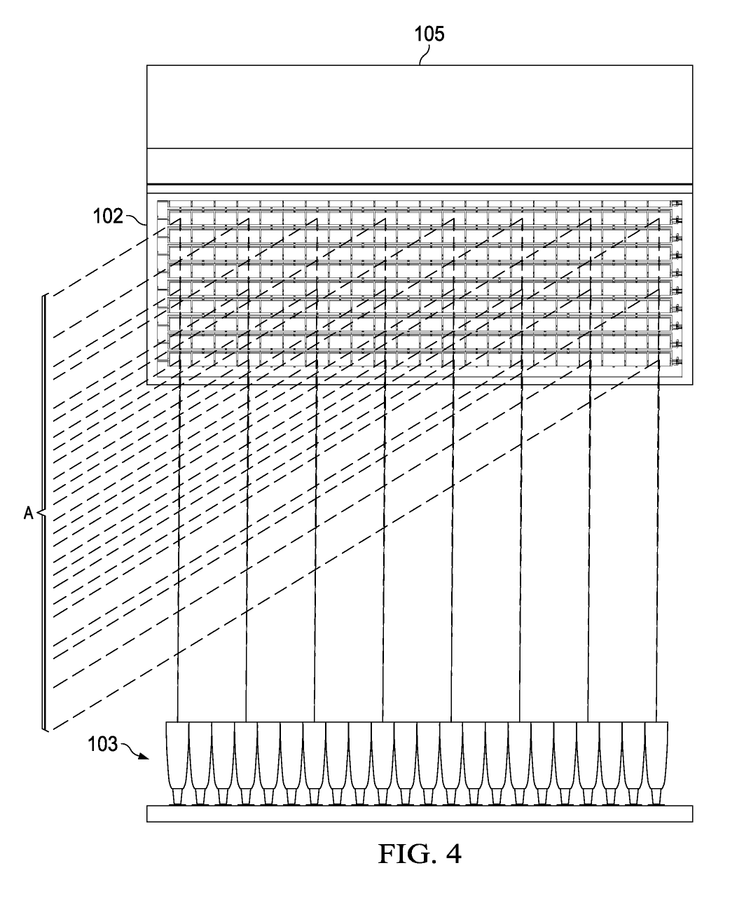

FIG. 3 and FIG. 4 are alternate views of the collector panel show the same elements that are shown in FIG. 2, except that FIG. 3 is a side view and FIG. 4 is a top view. As illustrated in FIG. 3, the collector panel 102 concentrates incoming solar radiation A in a vertical direction along a vertical axis. However, as illustrated in FIG. 4, the collector panel 102 does not concentrate solar radiation A in a horizontal direction along a horizontal axis.

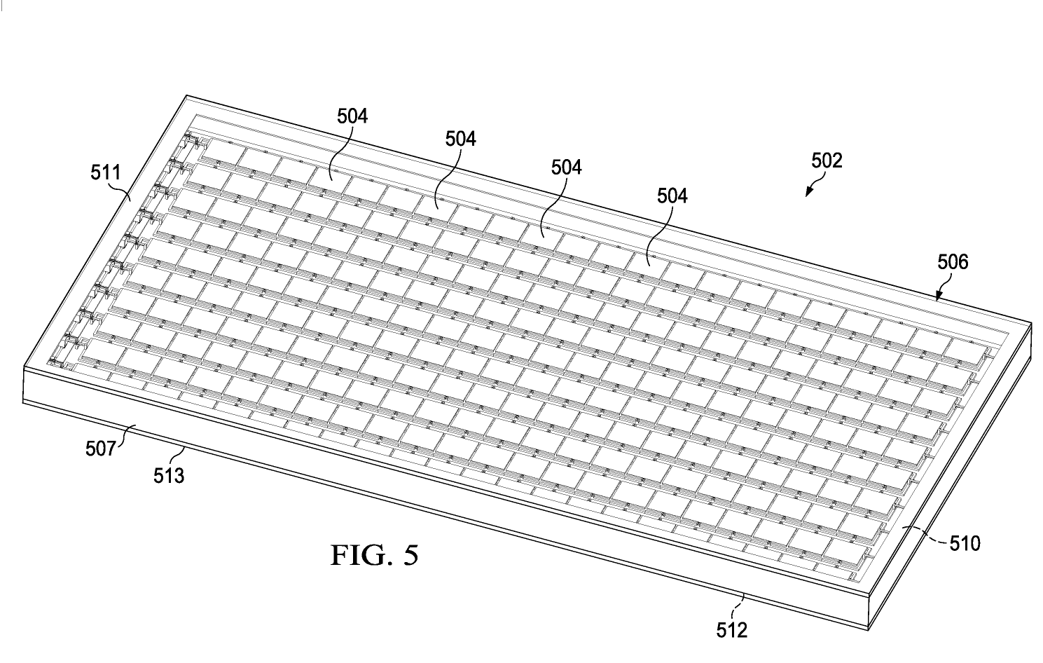

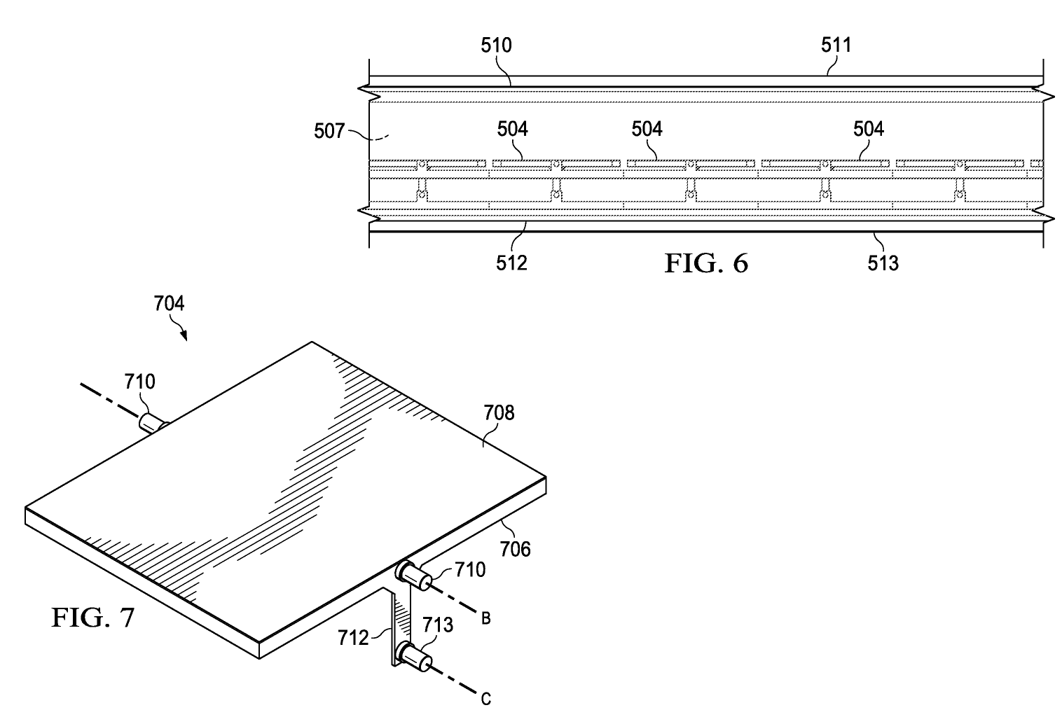

Referring now to FIGS. 5 and 6, there is shown a perspective view of a single collector panel 502 comprising an array of reflector elements 504 located inside a housing 506. The housing 506, in this embodiment, comprises a frame 507 having a front side 510 and back side 512. In one embodiment, the front side 510 of frame 507 may comprise a transparent window 511 attached to the front side 510 and a backing 513 attached to the back side 512. In one embodiment, the front side 510 and back side 512 are configured to enable the window 511 and backing 513 to be attached directly thereon. In another embodiment, the front side 510 and back side 512 may comprise flanges. The frame 507, window 511, and backing 513, in one embodiment, are configured to form an enclosure such that the reflector elements 504 are completely enclosed within the housing 504. The frame 507 also serves to provide structural support for the reflector elements 504 enclosed within, as well as the window 511 and backing 513 attached thereto. The window 511 allows solar radiation in and out of the housing 506, while keeping out dirt, other particulates, wind, water, other weather elements, and other contaminants that may interfere with operation of the collector panel 502.

In one embodiment, the frame 507 comprises a thickness of about 4 inches, which provides enough height such that the reflector elements 504 may move unhindered within the housing 506. In another embodiment, the frame 507 comprises a length of about 8 feet and a width of about 4 feet. The window 511 and backing 513 may comprise similar length and width dimensions as they are supported or coupled to the frame 507. Other lengths, widths, and thicknesses may be appropriate in other embodiments accordingly.

The frame 507 may be fabricated from materials comprising metal, plastic, wood, or other materials suitable for rigid, structural support of the components of and within housing 506. In one embodiment, frame 507 comprises extruded aluminum beams that are welded or joined together via a suitable metal coupling method. The transparent window 511 may comprise a thin sheet of transparent acrylic, but may also comprise polycarbonate, float glass, or other suitable transparent materials for allowing passage of solar rays therethrough. Backing 513 may comprise a transparent or opaque surface. In one embodiment backing 513 may comprise a thin sheet of plastic such as polyester, but other materials such as metal or glass sheets are also suitable.

Window 511 and backing 513 may be bonded to frame 507 by adhesive bonding, but other attachment methods such as mechanical fasteners or rubber gasket seals may be suitable. During attachment, the window 511 and/or the backing 513 may be stretched over frame 506 to increase strength and reduce any sag of either window 511 and/or backing 513.

Referring now to FIG. 7, there is shown a perspective view of a single reflector element 704. Reflector element 704, in this embodiment, comprises a substrate 706 having a reflective surface 708. Two upper rotational shafts 710 extend co-linearly from opposing sides of substrate 706, forming a rotational axis B about which the reflector 704 can rotate. Also, in this embodiment, a lever arm 712 extends beneath the substrate 706, with lower rotational shaft 713 extending from the distal end of lever arm 712. In another embodiment, a second lever arm 712 and lower rotational shaft 713 may be positioned on the opposing side of substrate 706. The lower rotational shaft 713 and lever arm 712 form a second rotational axis C parallel to the first rotation axis B.

In one embodiment, the reflector surface 708 has a surface area of about 10 cm×10 cm square, and lever arm 712 extends about 3.5 cm below reflector surface 708. The substrate 706, upper rotational shafts 710, lever arm 712, and lower rotation shaft 713 are injection molded as a single plastic part. Substrate 706 may be approximately 1 mm thick, with ribs extending downward along the outer periphery of the substrate for added strength and stiffness. The reflector surface 708 comprises a metalized polymer film laminated onto substrate 706, thereby making reflector surface 708 reflective. However, other embodiments of reflector elements may utilize other shapes, dimensions, and manufacturing processes, for example a 20 cm hexagonal reflector that is fabricated through CNC milling and reflectorized with vacuum metallization process. Also, in other embodiments the rotational shafts 710 and 713 may be replaced by another feature that enables rotational movement.

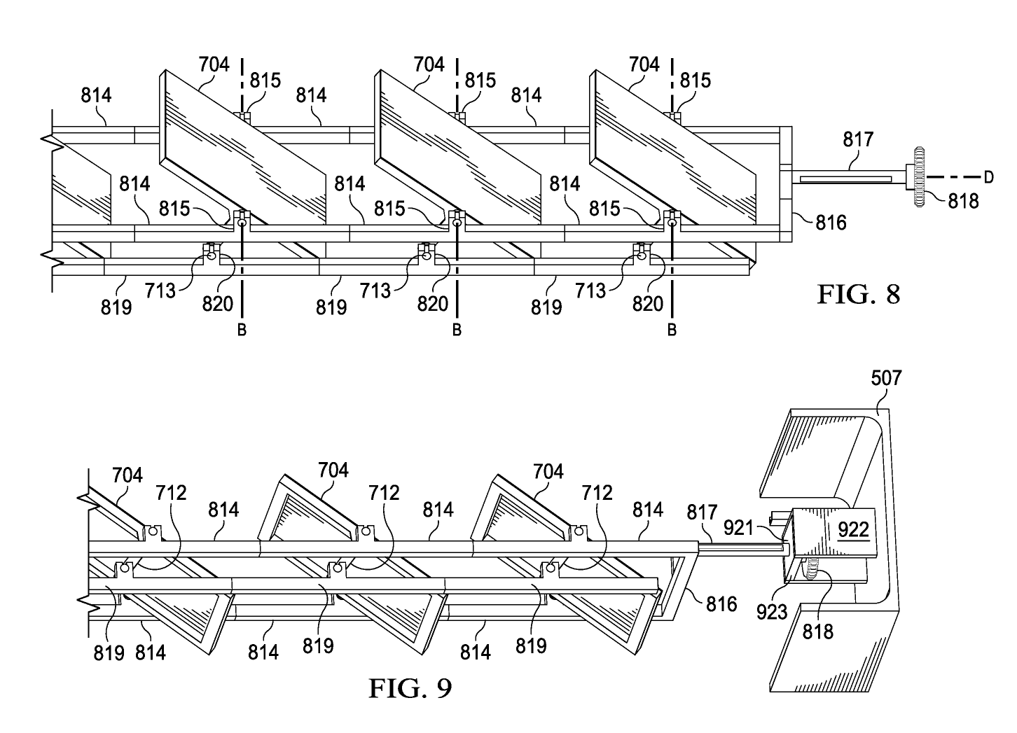

Referring now to FIG. 8, there is shown a row of reflector elements 704 connected by a mechanical drive system 800 that allows reflector elements 704 to move in unison about a set of parallel first axes B and move in unison about a second axis D, the second axis D substantially orthogonal to the set of parallel first axes. By enabling rotation about two axes, the reflector elements are configured to track a moveable electromagnetic radiation source, such as the sun. While FIG. 8 shows only a single row of reflector elements 704, a plurality of rows may be utilized in some embodiments of a solar concentration system according to the present disclosure. The reflector elements 704, in this embodiment, are suspended between a pair of upper rails 814. Upper rails 814 have attachment points 815 and spaced at regular intervals along the rails 814. Reflector elements 704 attach to the attachment points 815, which allow rotational movement along each axis B. In one embodiment, the attachment points 815 comprise apertures, such as through-holes, and the shafts 710 of reflector elements 704 are inserted into the apertures allowing rotation about the axis B. The upper rails 814 are connected with a crossbar 816, which maintains spacing between the upper rails 814 for positioning of the reflector elements 704 therebetween. The crossbar 816 is attached to a rotational shaft 817, which is centered between the upper rails 814. The rotation shaft 817 is attached to a gear 818 such as, for example, a worm gear. In one embodiment, axis of rotation D of the rotational shaft 817 passes through approximately a center of each reflector element 704 in the row, just grazing the reflective surface 708 when the element 702 positioned in a flat state, parallel to the upper rails 814. Although not shown, crossbar 816, rotational shaft 817, and gear 818 are also attached at opposite ends of the rails 814 at a distal end of each row (not shown). Pushrod 819 has attachment points 820 along its length at regular intervals similar to attachment points 815 on rails 814. The pushrod attachment points 820 are attached to rotational shaft 713 positioned near the end of lever arm 712, allowing rotation about axis C (as shown in FIG. 7).

Rotation of the gear 818 rotates shaft 817 which rotates the rails 814, which rotates all of the reflectors 704 mounted in the row in unison about rotational axis D. Pushing pushrod 819 distally away from crossbar 816 and then pulling pushrod 819 proximally toward crossbar 816 (respective to the view as shown in FIG. 8) creates parallelogram four-bar linkages between adjacent reflector elements 704, causing rotation about attachment points 820 and moving the levers 712 of, causing the reflector elements 704 to rotate with respect to the upper rails 814. This rotation occurs about rotation axes B, which are orthogonal to rotation axis D. In this way, the reflector elements are each able to rotate about two orthogonal axes independently and in unison with respect to each axis. The angle of rotation about axis D is substantially equal for all reflector elements 704 in a single row. Likewise, the angle of rotation about axes B is substantially equal for all reflector elements 704 in a single row.

In one embodiment, both of the rails 814 and the pushrod 819 may comprise a 2 mm×4 mm rectangular cross section of extruded plastic. In certain embodiments, the row of collectors 102 may have a length of about 8 feet long, so the length of rails 814 and pushrod 819 are less than 8 feet in length, accordingly, slightly less in length than the row of collectors. Attachment points 815 and 820 may have apertures measuring about 2 mm diameter, said apertures formed into the rails 814 and pushrod 819 by punching or drilling into the extruded plastic at intervals of about 10.1 cm. The crossbar 816, shaft 817, and the gear 818 are injection molded as a single plastic piece. This piece is attached to the rails 814 with a method such as ultrasonic welding, solvent welding, or adhesive bonding. The crossbar 816 may be about 4 mm tall, 2 cm wide, and 10 cm long. The rotational shaft 817 may be approximately 6 mm in diameter, and the gear 818 may be approximately 30 mm in diameter. The materials, dimensions, and manufacturing processes are provided herein as examples and are not intended to limit the scope of the disclosure.

When positioned in a row of collectors having about an ft. span, the rails 814 may not be able to support the reflector elements 704 across the 8 ft. span without sagging in certain points, and in particular, near the center of the row. Accordingly, the rails 814 may be mounted in tension by stretching the rails 814 on the frame 507 of housing 506, as shown in FIG. 9. Accordingly, anchor plates 921 may be positioned at one or both ends of the row of elements 704. Anchor plates 921 are attached to the housing frame 507 by supports 922. The gear 818 is snapped into the anchor plate 921 at one end of the row and then stretched and snapped into the anchor plate 921 at the other end of the row. The snap joint is located at a bottom edge 923 of anchor plate 921. In some embodiments, the row may be stretched such that the gears 818 are able to fit behind the anchor plates 921 because the distance between the anchor plates 921 on either side of the row is larger than the distance between the gears 818 on either side thereof. The anchor plates 921 accordingly push outwardly on the gears 818, keeping the shaft 817 and the rails 814 in tension. The supports 922 transfer the tension force to the frame 507, which is configured and constructed to support the row. Note that the crossbar 816 may be configured such that it does not relax the tension in the rails 814. The anchor plate 921 and supports 922 may be formed by injection molding of a plastic or polymer and bonded to frame 507, or may be fabricated as part of the frame 507.

Alternative designs of the rows are also within the scope of the disclosure. For example, a single rail running beneath the center of the reflector elements with a gimbal support extending from the rail to attach to the reflector elements. An important feature of the system is a mechanical design that allows the row to rotate about both axes B and axis D in FIG. 8 simultaneously and independently, with control surfaces located at least one end of the row.

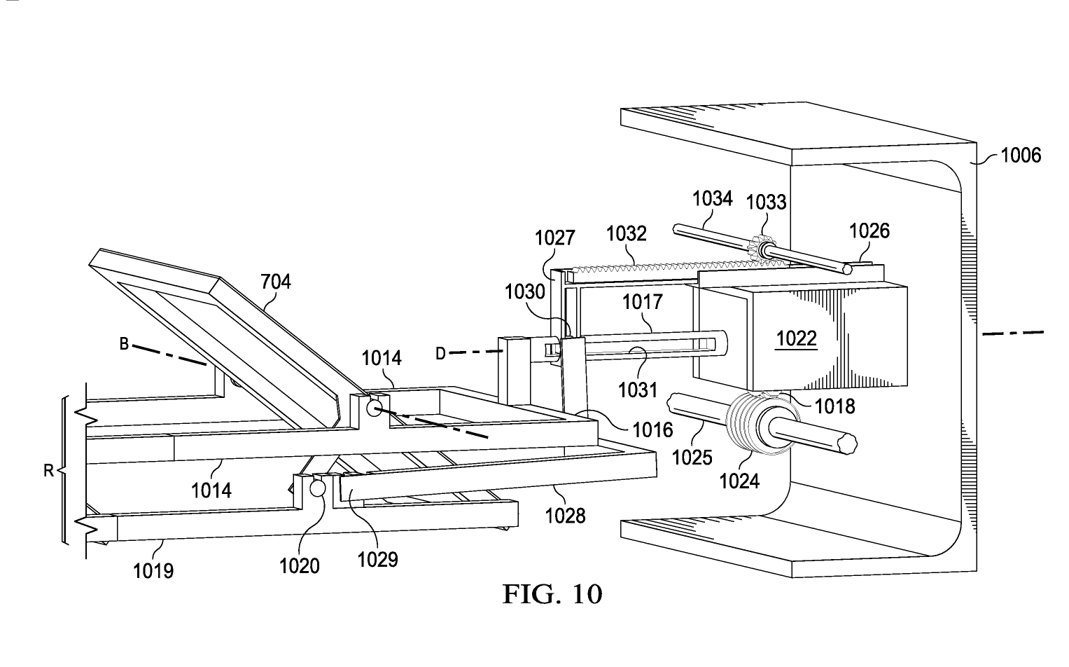

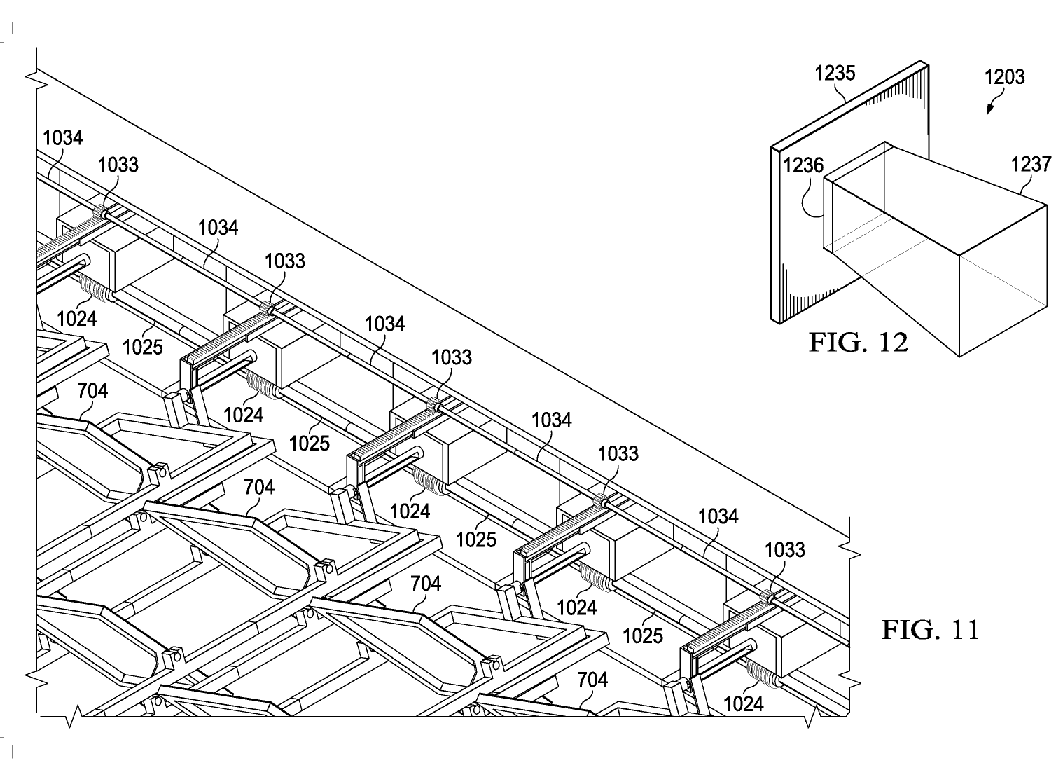

FIG. 10 shows a detailed view of one embodiment of a mechanical drive system 1000 which may be used with the collector panel 502 in one embodiment of a solar concentration system according to the present disclosure. The mechanical drive system 1000 comprises a worm gear 1018 driven by a worm 1024. Worm 1024 may be fastened to rotating shaft 1025, which is perpendicular to the row and parallel to axis B. All rows R in the collector panel 502, in this embodiment, are substantially identical to the row described hereinabove with respect to FIGS. 8 and 9, and all may have an associated worm 1024 to drive the row rotation. All worms 1024 may be connected to the same drive shaft 1025, as shown in FIG. 11. Thus, a given angular rotation of drive shaft 1025 may cause all rows R to rotate, and the angular displacement of all of the rows may be substantially equal. Drive shaft 1025 may be driven by a single electric stepper motor coupled to the shaft through a pair of reducing spur gears. The drive system on both ends of an array of collectors may be symmetric, such that each row R is driven similarly from both ends. Accordingly, a second electric stepper motor that drives a second drive shaft 1025 may be positioned at the distal end of the array of collectors (relative to the proximal end shown in FIGS. 10 and 11). The two electric motors are substantially synchronized to provide substantially equal amounts of rotation to avoid twisting of the rows. Although the mechanical drive system 1000 is shown and described utilizing a worm drive, other drives and gear arrangements may be used without departing from the spirit of the disclosure.

As shown in FIG. 11, there may be a rotation angle constant offset between adjacent rows such that each row R directs incident radiation towards a secondary concentrator. The concentration factor in this configuration is relatively equal to the number of rows. In one embodiment there are approximately 10 rows. While each row is configured to rotate in unison about a first set of parallel axes, such as axes B shown in FIG. 8 and in unison about a second axis such as axis D shown in FIG. 8, adjacent rows, while likewise rotating about a respective set of axes B with substantially similar angular displacement and angular position, and while likewise rotating about a respective axis D with substantially similar angular displacement, may have an offset in absolute angular position. While respective axes D for adjacent rows may be substantially parallel, respective axes B for reflectors in adjacent rows may not be parallel. Furthermore, referring back to FIG. 8, the surface of the reflector elements 704 may be slightly curved about axis D. The curvature may comprise a 2D parabola with a focus located at receiver 103 (as shown in FIGS. 1 and 2). Such a configuration provides additional concentration across all angles of solar incidence, resulting in a total concentration factor from this collector configuration of approximately 20.

Referring again to FIG. 10, the pushrod 1019 may be coupled to a one-dimensional slider 1027 by way of a rotating arm 1028. The slider 1027 is constrained by slider base 1026 to slide in only one direction, parallel to axis D. The rotating arm 1028 connects to pushrod 1019 at a rotational attachment point 1029 and connects to slider 1027 at a sliding rotating attachment point 1030. Sliding rotating attachment point 1030 is preferably located along the axis of rotation D, which enables rails 1014 to rotate while slider 1027 remains stationary and likewise enables slider 1027 to move while the rails 1014 remain stationary. As a result, the two axes of rotation, axis B and axis D, are independent. In one embodiment, the rotating sliding attachment point 1030 is guided by a slot 1031 in rotating shaft 1017.

A rack gear 1032, in this embodiment, may be mounted on the slider 1027. The rack gear 1032 may be coupled to a pinion gear 1033, which is mounted on a shaft 1034 that runs parallel to the other drive shaft 1025. As shown in FIG. 11, the associated pinion gears 1033 for all rows may be mounted on the same drive shaft 1034. An electric stepper motor may be coupled to drive shaft 1034 by a pair of reducing spur gears. Configuring drive shaft 1034 with a given angular displacement enables substantially equal linear displacement in the sliders 1027 in all rows, which thereby enabling substantially equal angular rotation about axes B relative to the rails 1014 in a given row for all reflector elements in the collector. Since there is no offset in slider position between adjacent rows in this embodiment, all reflector elements in the collector maintain substantially equal positions about axes B. Accordingly, the collectors in this embodiment do not concentrate light in the horizontal direction.

The worm 1024, drive shaft 1025, slider base 1026, slider 1027, swing arm 1028, rack gear 1032, pinion gear 1033, and drive shaft 34 may be fabricated by injection molding of plastic, extruded plastic, extruded aluminum, or any other suitable material and manufacturing process for fabricating plastics or metal for use in a mechanical drive system.

The stepper motors may be driven by electrical signals generated by a controller. As the sun moves across the sky, the controller measures the sun's position either through a closed loop machine vision system, or through a location based astronomical algorithm for determining sun position, or by querying an external source or by some combination of methods. Based on the position of the sun, the controller calculates what position the reflector elements need to be in such that they direct incident solar radiation into the receiver aperture. Based on information on the components of mechanical drive system such as gear ratios and the current position of the reflector elements, the controller calculates how many steps the motor may move, and generates the electrical signals to send to the motor to cause the movement.

The controller may communicate with the mechanical drive system via a wired or wireless communication system, and likewise may communicate with other computing devices either positioned on site with the solar concentration system of the present disclosure, or a remote controller and/or computing device, including, but not limited to various mobile communication devices and control systems which may be user in connection with solar energy and collection systems.

Referring now to FIG. 12, there is shown a photovoltaic cell sub-assembly 1200 comprising one embodiment of an energy conversion cell which may be used in conjunction with embodiments of solar concentration systems according to the present disclosure. The sub-assembly 1200 may comprise a direct-bond copper circuit board substrate 1235, onto which is bonded a photovoltaic cell 1236. The circuit board 1235 may contain additional and/or optional semiconductor components that are used to support the photovoltaic cell 1236.

On top of photovoltaic cell 1236 may be a secondary concentrator assembly including a homogenizer 1237, configured in a tight fit to ensure all of the concentrated light hits the photovoltaic cell 1236. The circuit board 1235 may have a dimension of approximately 1.2 in×1.2 in, with a thickness of about 1 mm. The photovoltaic cell 1236 is a high concentration triple junction type III-V semiconductor cell that may be soldered on circuit board 1235, facilitating heat transfer between the cell 1236 and the circuit board 1235. In one embodiment, the photovoltaic cell 1236 may have a dimension of approximately 1 cm×1 cm, with a thickness of about 0.5 mm; however, the photovoltaic cell 1236 may be larger or smaller in size, whereby homogenizer 1237 and circuit board 1235 may be altered to support the difference in size. The homogenizer 1237 may comprise a square cross section pyramidal optical element. Homogenizer 1237 may be made of a solid molded transparent material such as glass, silicone, polycarbonate, or acrylic and bonded onto the face of the photovoltaic cell 1236 with solar-grade silicone adhesive, or other suitable adhesive methods. The homogenizer 1237 may have dimensions of about 1 cm×1 cm at an exit aperture connected to the photovoltaic cell, and about 2 cm long and about 1.25 cm×1.25 cm at an entry aperture. These dimensions enable a concentration ratio of about 1.56. The homogenizer 1237 works through principle of total internal reflection to homogenize a beam of radiation. The entry aperture may be coated with an anti-reflective coating to minimize energy loss due to reflection. The photovoltaic cell 1236 converts incident light directly into direct current electricity and heat. In an alternative embodiment, the homogenizer 1237 may be comprised of a hollow tapered square prism with reflective interior sidewalls and may operate through the principle of traditional reflection.

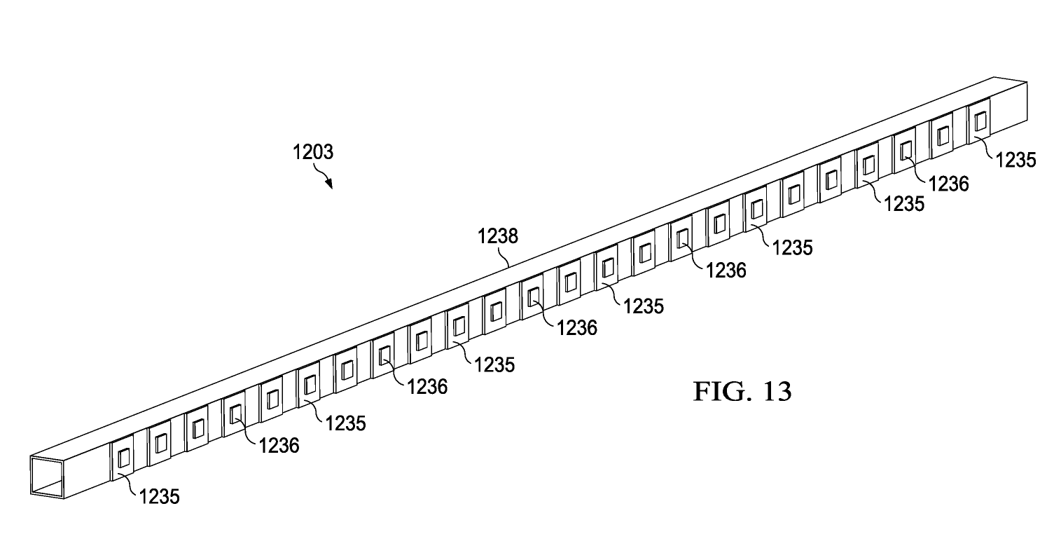

Referring now to FIG. 13, there is shown a support member, such as pipe 1238, which may be used with a receiver assembly 1203 according to the present disclosure. The support member may include a heat sink thermally coupled to the plurality of photovoltaic cells. In this embodiment, the support member comprises a liquid cooling pipe 1238 having circuit boards 1235 and photovoltaic cells 1236 attached thereto every 10 cm pitch across the pipe 1238. The pipe 1238 may comprise extruded aluminum or copper and the circuit board may be connected to the pipe using an appropriate solder which provides for optimal heat transfer from the circuit board 1235 to the pipe 1238. The pipe 1238 may have a square cross section and dimensions of approximately 1.2 in×1.2 in and 8 feet long. Water is flowed through the pipe at a steady rate, which allows the heat to transfer from the photovoltaic cell to the circuit board to the pipe and then to the water. The photovoltaic cell may tend to get very hot due to the incidence of highly concentrated solar radiation. The water serves as a liquid coolant which may be controlled by flow rate to ensure that the photovoltaic cells 1236 remain within their operating temperature. The heated water can thereafter be transported through a plumbing network for remote use, such as to heat a building, and various other uses for heated water at an installation location. An external pump and control system may adjust the water flow rate to achieve a desired heating of water and cooling of the photovoltaic cells. If proper cooling cannot be achieved, the external control system signals the internal control system to de-focus the concentrator mirrors, effectively turning the system off. The pump and control system may likewise be controlled by a controller and be configured to communicate with a control system, which may comprise one or more computing devices and/or mobile computing devices.

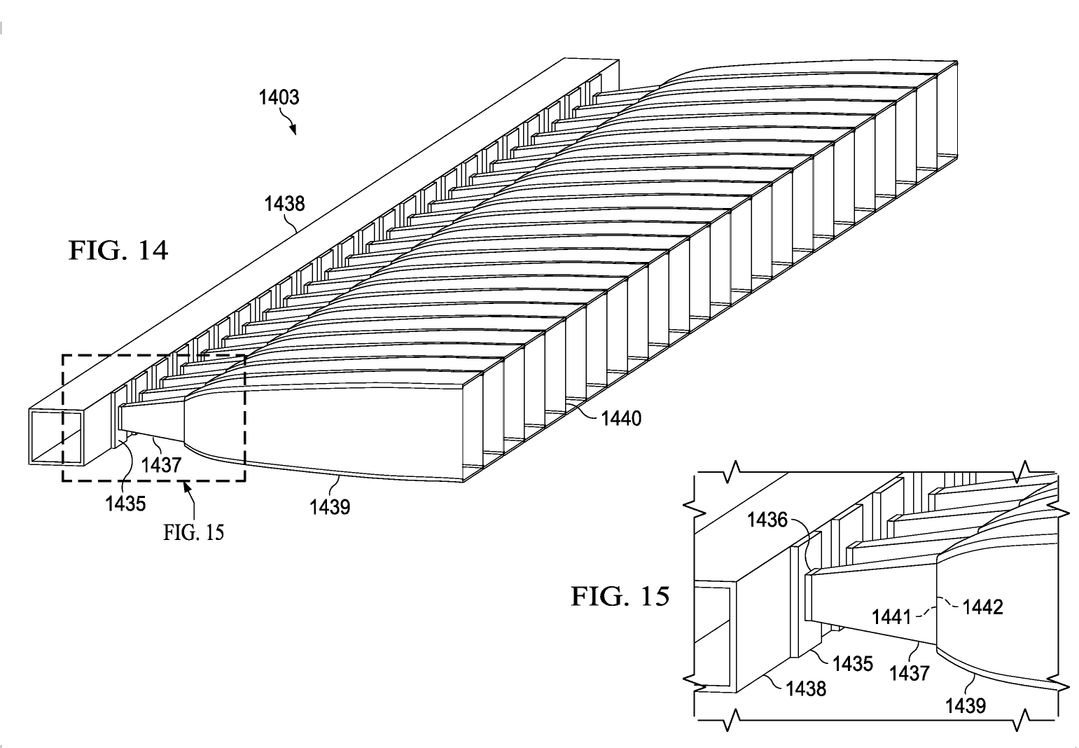

Illustrated in FIG. 14 and FIG. 15 is a receiver assembly 1403 having pipe 1438, homogenizers 1437, photovoltaic cells 1436, circuit board 1435, and secondary concentrators 1439. FIG. 15 provides an enlarged view of the configuration of pipe 1438, cells 1436, and homogenizers 1437, showing the connections between the various elements of receiver 1403. The secondary concentrator 1439 may be a non-imaging optic element that provides two dimensional concentration of incident solar radiation. In one embodiment, the secondary concentrator is a three-dimensional compound parabolic shape having a rectangular cross-section. However, several other types of non-imaging optics may be used, including non-imaging Fresnel lenses and trumpet concentrators. The secondary concentrator 1439 may be formed by injection-molded plastics having interior surfaces laminated with a metalized polymer film, rendering them highly reflective. The secondary concentrator 1439 is designed having a 10 degree acceptance half-angle in the vertical direction and a three degree acceptance half-angle in the horizontal direction. The secondary concentrator 1439 may also be configured with a 60 degree exit angle such that radiation exiting the secondary concentrator 1439 may enter the homogenizer 1437 without being reflected. The entry aperture 1240 of each secondary concentrator 1439 is approximately 10 cm wide and 5 cm tall. The exit aperture may be a 1.25 cm×1.25 cm square, in one particular embodiment. The secondary concentrators 1439 are aligned such that exit 1441 aperture of the secondary concentrator 1439 and the entry aperture 1442 of the homogenizer 1437 are coincident. The entry apertures 1440 of the secondary concentrators 1439 are abutted next to each other, such that their entry apertures 1440 merge together to form one long aperture, such as rectangular aperture 106 as shown in FIG. 1. Accordingly, a total collective aperture for the receiver 1403 may be about 8 feet long by 5 cm tall rectangle. Since the horizontal acceptance half angle for the secondary concentrators 1439 may be about 3 degrees, this allows for about 3 degrees of horizontal optical error from a collection panel such as collection panel 102. Further, since the parabolic curvature of the reflector elements 704 result in approximately 5× concentration, a perfectly aligned system with no error requires only about a 2 cm tall receiver aperture. Accordingly, since the actual aperture is about 5 cm tall, a vertical error of about 1.5 cm is allowed the receiver, which translates to about 0.6 degrees of acceptable vertical error from the collection panel 102. Referring back to FIG. 1, the receiver 103 is angled such that the primary axis of the secondary concentrators bisects the rim angle of the collector panels 102. The distance between the collector panel 102 and the receiver may be approximately 2 m. Thus, the rim angle of the system is about 10 degrees, which corresponds with the secondary concentrator 1439 vertical acceptance angle.

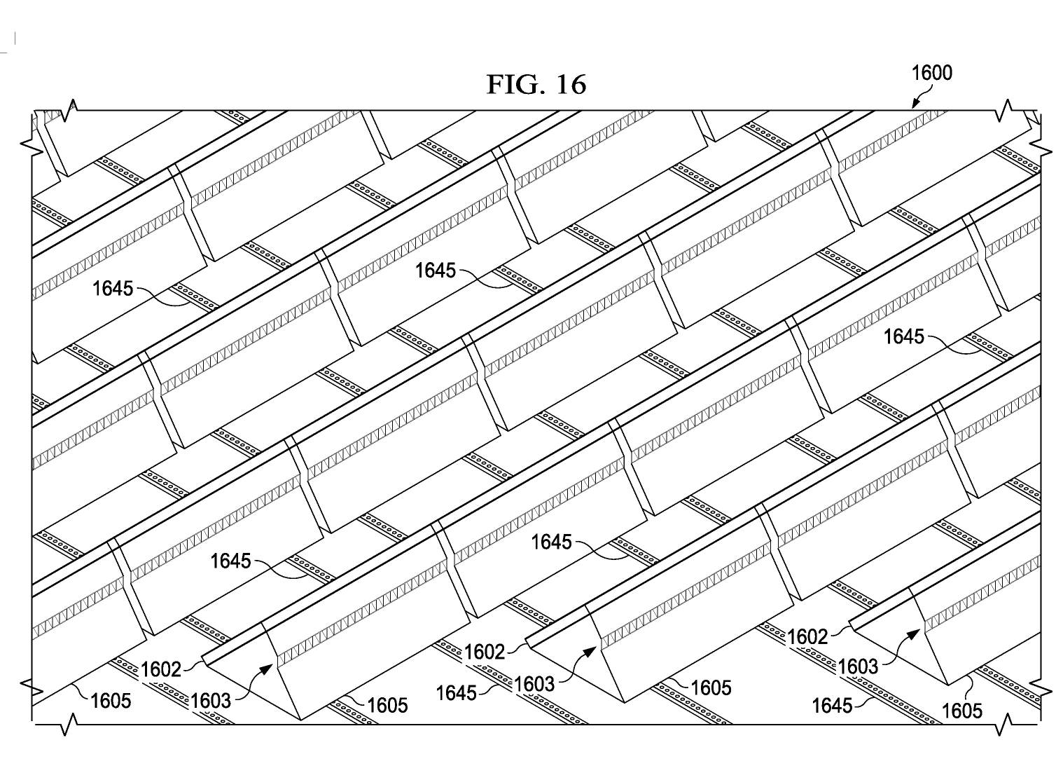

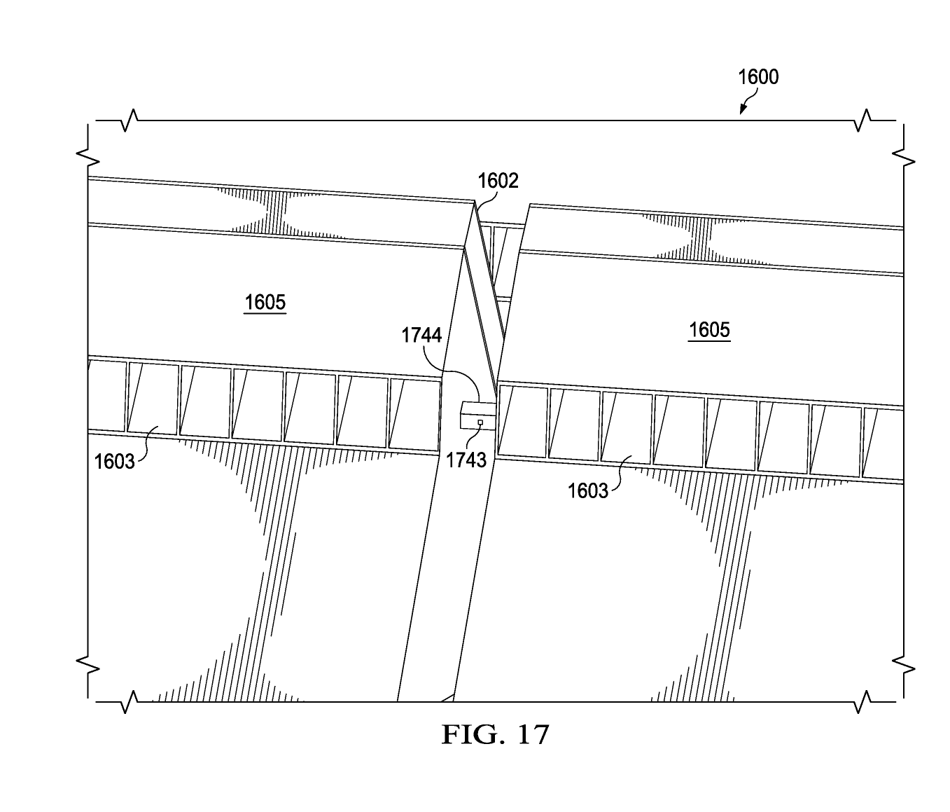

Referring now to FIG. 16, there is shown an installation of a solar concentration system 1600 having collector panels 1602 organized in southward-facing rows (northward facing in the southern hemisphere) and mounted on rackings 1605. The receivers 1403 for each row are mounted in the racking 1605 of the preceding row. If there is no preceding row, then the receivers are mounted on stand-alone racking without any collector panel. The rackings 1605 are configured to be interconnecting through racking extensions 1645, which enables a more precise spacing between rows and makes installation easier. The racking 1605 may also be designed with an aerodynamic casing for improved aerodynamic performance, such that wind flows over the panels without producing high wind load forces on the panels. The racking 1605 may be fabricated from extruded aluminum, and the aerodynamic casing may be fabricated from aluminum or plastic sheets. A transparent window similar to window 511 may comprise anti-reflective coating and protect the receiver 1603, keeping out particulates and weather elements such as wind, water, etc. The window may be fabricated from glass, acrylic, polymers, and other suitable substantially transparent materials.

Referring now to FIG. 17, there is shown an enlarged, close-up view of two adjacent collector panels 1602 having receivers 1603, illustrating a gap between units when installed. The units have approximately a 10 cm wide gap space with a pipe connection 1744 made therein. The pipe connection 1744 is designed such that the connection can be made easily once the panels 1602, receivers 1603, and racking 1605 have been set in place. The pipe connection 1744 may be a standard threaded pipe union. Also in the gap is electrical connection 1743. The electrical connection 1743 connects together the electrical outputs of each receiver unit. The outward facing secondary concentrator openings are shown flush against the system aluminum casing adding to the aerodynamic system design. In one embodiment of the disclosure, micro-inverters are integrated into each receiver assembly. These micro-inverters invert the direct current (DC) produced by the photovoltaic cells into grid-quality alternating current (AC), while simultaneously preforming maximum power point tracking on the photovoltaic cells. These micro-inverters could run from the same real-time micro controller as the collector panel mechanical controller. The electrical connection 1743 may be configured as an AC connection. The connected electrical current outputs may then be utilized similar to collected energy in traditional microinverter solar energy systems. In another embodiment of the disclosure, a DC-to-DC converter implementing maximum powerpoint tracking (MPPT) is integrated into each receiver assembly. These DC-to-DC converters may communicate with the collector panel mechanical controller. The electrical connection 1746 may be configured as a DC connection. The connected electrical current outputs may then be fed into a solar inverter in a manner similar to traditional solar energy systems.

The solar concentration system 1600 as shown in FIGS. 16 and 17 may be mounted on a rooftop or other surface suitable for placement of the concentration system 1600 where the collectors 1602 will have optimum access to sunlight. The rooftop or mounting surface may be substantially flat, or may be sloped at an angle of up to about 20 degrees. The collectors are mounted on one side of the rackings 1605 and the receivers 1603 are mounted on the opposing side of the rackings 1605. The rackings 1605 are configured with extensions 1645 that connect adjacent rows of racking 1605 such that a specific spacing is maintained between the collectors 1602 and the associated receivers 1603. Each system 1600 may be configured modularly to facilitate two or more rackings to accommodate a plurality of collector/receiver systems according to a mounting space configuration and/or energy requirements for an installation location.

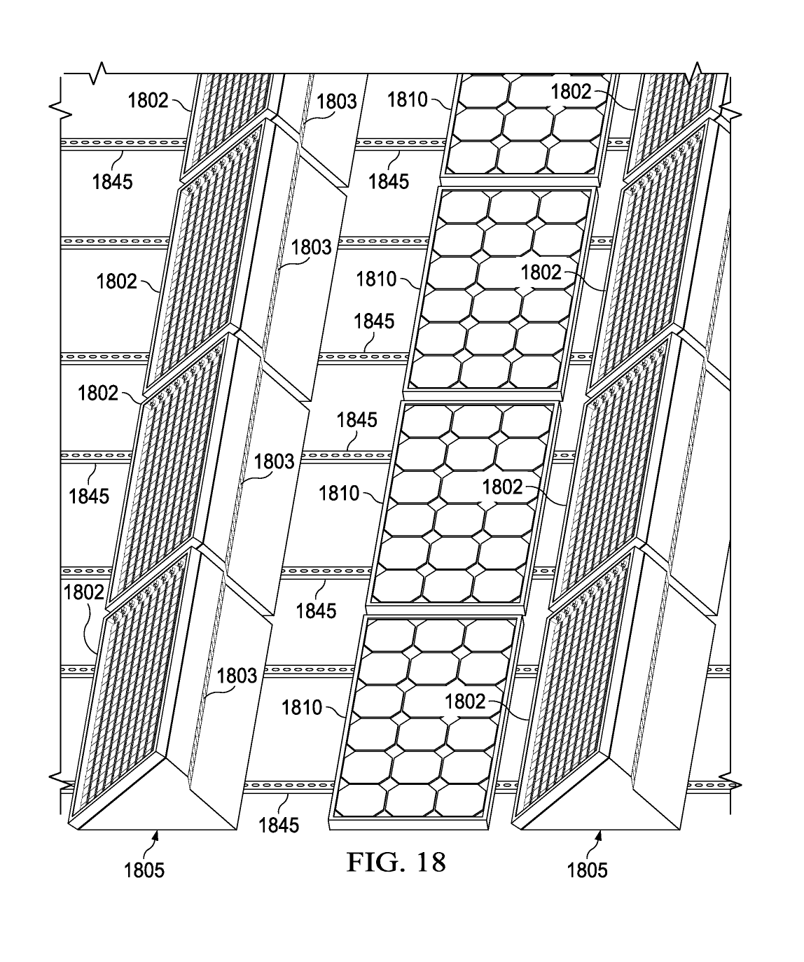

Referring now to FIG. 18, there is shown an alternate embodiment of a solar concentration system 1800 according to the present disclosure. In this system 1800, traditional flat solar panels 1810 may be used in conjunction with collector panels 1802 and receivers 1803 according to the present disclosure. The traditional solar panels 1810 may be positioned between the rows and be used to collect more energy for use at an installation site. The traditional solar panels, such as those constructed and used frequently in residential, commercial, and utility-scale installations may likewise be connected to a system controller for the solar concentration system. A traditional solar panel 1810 may provide electrical power to the electrical stepper motors located within concentrator panel 1802 in accordance to the present disclosure. An extra DC-to-DC converter implementing MPPT or an extra microinverter may be located in concentrator panel 1802 in order to ensure maximum power output from traditional solar panel 1810. The traditional solar panels 1810 are mounted on racking extensions 1845.

While the foregoing written description of the disclosure enables one of ordinary skill to make and use what is considered presently to be the best mode thereof, those of ordinary skill will understand and appreciate the existence of variations, combinations, and equivalents of the specific embodiment, method, and examples herein. The disclosure should therefore not be limited by the above described embodiment, method, and examples, but by all embodiments and methods within the scope and spirit of the disclosure.

1. A panel, comprising:
a frame; and
a plurality of moveable reflector elements mounted within the frame, the plurality of movable reflector elements configured to rotate in unison about a set of parallel first axes and in unison about a second axis relative to an electromagnetic radiation source;
wherein the plurality of movable reflector elements are configured to reflect electromagnetic radiation from the electromagnetic radiation source onto an energy transformation medium for transforming the electromagnetic radiation into electrical or thermal energy.

2. The panel according to claim 1, wherein the plurality of movable reflector elements are a first plurality of movable reflector elements located in a first row, and further including a second plurality of movable reflector elements located in a second row, wherein the second plurality of movable reflector elements are configured to rotate in unison about a set of parallel third axes and in unison about a fourth axis relative to the electromagnetic radiation source.

3. The panel according to claim 2, wherein the second and fourth axes are proximal and substantially parallel to one another.

4. The panel according to claim 3, wherein the first plurality of movable reflector elements are configured to rotate about the set of parallel first axes such that the rate of angular displacement is substantially identical to the rate of angular displacement that the second plurality of movable reflector elements are configured to move about the set of parallel third set of axes.

5. The panel according to claim 1, wherein the frame comprises a front side and a back side, a window coupled proximate the front side, and a backing coupled proximate the back side, wherein the frame, window, and backing form an enclosure.

6. The panel according to claim 1, wherein each reflector element comprises:
a substrate having a reflective surface, a pair of upper pivoted supports located co-linearly on opposing sides of the substrate, which form the first rotational axis;
a lever arm extending beneath the substrate; and
a lower pivoted support located at the distal end of the lever arm.

7. The panel according to claim 6, wherein the plurality of moveable reflector elements are supported within the frame by a support member, the support member coupled to a pair of upper rails and a pushrod positioned below the pair of upper rails, wherein each reflector element is coupled between the pair of rails such that the upper pivoted supports are rotatably coupled to the rails and the lower pivoted support is rotatably coupled to the pushrod.

8. The panel according to claim 7, wherein the pair of the upper rails is coupled to a first drive shaft and the pushrod is coupled to a second drive shaft.

9. The panel according to claim 1, further comprising a controller associated with the plurality of movable reflector elements, the controller configured to determine a position of the electromagnetic radiation source for facilitating movement of the plurality of moveable reflector elements.

10. The panel according to claim 9, wherein the electromagnetic radiation source is the sun and the controller determines the position of the sun by one of calculation, measurement, or querying an outside data source.

11. The panel according to claim 1, wherein the energy transformation medium comprises:
a receiver comprising a support member; and
a plurality of energy conversion cells positioned along the support member at regular intervals, each energy conversion cell having an electromagnetic radiation concentrator protruding therefrom, the electromagnetic radiation concentrator comprising an optical element and an entry aperture at a distal end thereof;
wherein each energy conversion cell comprises a photovoltaic cell or thermal absorber.

12. The panel according to claim 11, further including a heat sink thermally coupled to the plurality of energy conversion cells.

13. The panel according to claim 12, wherein the heat sink is a liquid cooling pipe coupled to the support member.

14. The panel according to claim 11, wherein the receiver further comprises:
a plurality of circuit boards onto which each energy conversion cell is bonded thereto; and
a homogenizer protruding from each energy conversion cell and coupled with the electromagnetic radiation concentrator.

15. A solar concentration system, comprising:
at least one solar collector panel, the panel comprising:
a frame; and
a plurality of moveable reflector elements mounted within the frame, the plurality of movable reflector elements configured to rotate in unison about a set of parallel first axes and in unison about a second axis relative to the sun; and
at least one receiver, the receiver comprising:
a support member; and
a plurality of energy conversion cells positioned along the support member at regular intervals, each energy conversion cell having an electromagnetic radiation concentrator protruding therefrom, the electromagnetic radiation concentrator comprising an optical element and an entry aperture at a distal end thereof;
wherein the plurality of movable reflector elements are configured to reflect electromagnetic radiation from the sun onto the at least one receiver for transforming the electromagnetic radiation into electrical or thermal energy.

16. The solar concentration system according to claim 15, further including a heat sink thermally coupled to the plurality of energy conversion cells.

17. The solar concentration system according to claim 16, wherein the heat sink is a liquid cooling pipe coupled to the support member.

18. The solar concentration system according to claim 15, wherein the plurality of movable reflector elements are a first plurality of movable reflector elements located in a first row, and further including a second plurality of movable reflector elements located in a second row, wherein the second plurality of movable reflector elements are configured to rotate in unison about a set of parallel third axes and in unison about a fourth axis relative to the sun, and further wherein the a plurality of energy conversion cells positioned along the support member at regular intervals are positioned in a third row, wherein the first plurality of movable reflector elements located in the first row and the second plurality of movable reflector elements located in the second row are configured to reflect the electromagnetic radiation from the sun onto associated ones of the plurality of energy conversion cells positioned in the third row.

19. The solar concentration system according to claim 15, further comprising a controller associated with the plurality of movable reflector elements, the controller configured to determine a position of the sun for facilitating movement of the plurality of moveable reflector elements.

20. A method of manufacturing a panel, the method comprising:
forming a frame;
forming a plurality of moveable reflector elements to be mounted within the frame, the plurality of movable reflector elements configured to rotate in unison about a set of parallel first axes and in unison about a second axis relative to an electromagnetic radiation source; and
configuring the plurality of movable reflector elements to reflect electromagnetic radiation from the electromagnetic radiation source onto an energy transformation medium for transforming the electromagnetic radiation into electrical or thermal energy.
